(19) United States
(12) Patent Application Publication
(10) Pub. No.: US 2025/0052783 A1
(43) Pub. Date: Feb. 13, 2025

(54) CONTACT PROBE FOR PROBE HEADS OF ELECTRONIC DEVICES AND CORRESPONDING PROBE HEAD

(71) Applicant: TECHNOPROBE S.P.A., Cernusco Lombardone (LC) (IT)

(72) Inventor: Riccardo VETTORI, Cernusco Lombardone (LC) (IT)

(73) Assignee: TECHNOPROBE S.P.A., Cernusco Lombardone (LC) (IT)

(21) Appl. No.: 18/719,473

(22) PCT Filed: Dec. 19, 2022
(86) PCT No.: PCT/EP2022/086755

§ 371 Date: Jun. 13, 2024

(30) Foreign Application Priority Data
Dec. 29, 2021 (IT) 102021000032882

(51) Int. Cl. G01R 1/067; G01R 1/073

(52) U.S. Cl. CPC G01R 1/06716; G01R 1/06733; G01R 1/073

(57) ABSTRACT

A contact probe is disclosed having a first end portion which ends with a contact tip configured to abut onto a contact pad of a device under test and a second end portion which ends with a contact head configured to abut onto a contact pad of a board of a testing apparatus, as well as a probe body extended between the first end portion and the second end portion along with a longitudinal development axis The first end portion includes a first support part, interposed between the probe body and the contact tip. Suitably, the first support part includes at least one contact pin and one probe length which extend parallel to each other along the longitudinal development axis and are separated by an air gap.

### TECHNICAL FIELD

The present invention refers, in its most general aspect, to a contact probe for a probe head of electronical devices and the following description is made with reference to this field of application with the only purpose of simplifying the exposition thereof.

### BACKGROUND ART

As well known, a probe head is substantially a device adapted to electrically connect a plurality of contact pads of a microstructure, in particular an electronic device integrated on wafer, with corresponding channels of a testing apparatus which carries out the functionality testing, in particular electrical, or generically the test.

The test carried out on integrated electronic devices aims in particular to detect and isolate defective devices as early as during the manufacturing stage. Usually, the probe heads are then used for electronically testing the electronic devices integrated on wafer before cutting and assembling them inside a chip containment package.

A probe head usually comprises a great number of contact elements or probes formed by special alloys with good electrical and mechanical properties and provided with at least one contact portion with one of the contact pads of the device under test.

More in particular, a vertical probe head comprises a plurality of contact probes housed in guide holes made in at least one pair of plate-shaped guides, parallel to each other and placed at a certain distance so as to leave a free area or air gap for moving and eventually deforming the contact probes. The pair of guides particularly comprises an upper guide, positioned closer to the testing apparatus connected to the probe head, and a lower guide, positioned closer to a wafer comprising the devices under test, both guides being provided with respective guide holes within which the contact probes axially slide.

The good connection between the contact probes of the probe head and the contact pads of the device under test is guaranteed by the pressure of the probe head on the device, the contact probes, which are movable within the guide holes of the upper and lower guides, being subjected, during said pressing contact, to a bending inside the air gap between the two guides and a sliding inside the respective guide holes.

Furthermore, the bending of the contact probes in the air gap can be helped by a suitable configuration of the probes and guides thereof, as schematically shown in FIG. 1, the shown probe head being of the so-called shifted-plate type.

In such case, the probe head 10 comprises at least one pair of upper guides or dies, in particular a first upper guide 16 and a second upper guide 17, which are plate-shaped and parallel to each other, and a lower guide or die 18, the guides being provided with respective first upper guide holes 16A, second upper guide holes 17A and lower guide holes 18A within which the contact probes 11 slide. In other known embodiments, not shown in the figures, also the lower guide can be split in a lower guide and an intermediate guide, both provided with suitable guide holes for the sliding of the contact probes 11.

The first upper guide 16 and the second upper guide 17 are suitably shifted with respect to the lower guide 18, the term shifted meaning that the centre of respective first upper guide holes 16A, second upper guide holes 17A and lower guide holes 18A are misaligned with respect to each other and are instead not arranged along a same longitudinal direction, which is indicated with z in the local reference of the figure, said longitudinal direction z being perpendicular to a reference plane n, corresponding to a transversal development plane of the guides. Furthermore, the first upper guide 16 and the second upper guide 17 are shifted with respect to each other. Thereby, the contact probes 11 housed in the guide holes of said first upper guide 16, second upper guide 17 and lower guide 18 are deformed with respect to a longitudinal development axis HH thereof, corresponding to the longitudinal direction z of the local reference of the figure.

Each contact probe 11 comprises a probe body 11C substantially extended along the longitudinal development axis HH, a plurality of contact probes 11 being usually placed inside the probe head 10 with said longitudinal development axis HH that is placed orthogonal to the reference plane n.

Each contact probe 11 has at least one first contact end, indicated as contact tip 11A and adapted to abut onto a contact pad 12A of a device under test 12 made in a semiconductor wafer 13 which develops on the reference plane n and a second contact end, indicated as contact head 11B and adapted to abut onto a contact pad 14A of a board 14 connecting with a testing apparatus, such as an interface PCB board or a so-called space transformer, that is a PCB board which is capable of realise a spatial transformation in relation to the distribution of respective contact pads made on opposite faces thereof. The terms end or tip indicate herein and in the following a terminal portion, which is not necessarily pointed. In particular, when the probe head 10 carries out the test of integrated devices, the contact tips 11A of the contact probes 11 thereof come into pressing contact onto the contact pads 12A of the device under test 12, the probes bend and deform and the contact heads 11B thereof are also in a pressing contact with the contact pads 14A of the board 14, the contact probes 11 thus carrying out the mechanical and electric contact between the device under test 12 and the testing apparatus (not represented) of which the probe head 10 forms a terminal element.

Suitably, the second upper guide 17, when the first upper guide 16 is the guide closer to the board 14, in the direction z of the local reference of the figure, and the lower guide 18 are spaced by an air gap 19 which allows to deform the contact probes 11 during the operation of the probe head 10.

The deformation of the contact probes 11 guarantees that the respective contact tips 11A abut onto the contact pads 12A of the device under test 12 in an sloped manner with respect to the longitudinal direction z, so as to realise a sliding of said contact tips 11A on the contact pads 12A and thus a surface cleaning and scrub thereof, so as to guarantee the correct contact, which is not only mechanical but also electrical, between contact probes 11 and device under test 12.

It is equally important to guarantee a correct retain of the probes inside the probe head, in particular when the latter is not resting against a wafer of integrated circuits. Mechanisms are usually provided for this purpose in order to prevent the unwanted slipping out of the contact probes 11 from the probe head 10 in both directions of the longitudinal direction z, that is upwards and downwards, considering the local reference of the figure.

For this purpose, the contact head 11B of each of the contact probes 11 of the example of FIG. 1 is provided with an enlarged portion 11D, i.e. having a transversal diameter that is greater than the transversal diameter of rest of the probe body 11C and of the first upper guide holes 16A of the first upper guide 16, the term transversal diameter meaning herein and in the following a value of maximum dimensions of a section, even not circular, taken at the reference plane n. Said enlarged portion 11D allows to guarantee the abutment of the contact head 11B onto the first upper guide 16, preventing the sliding of the contact probe 11 downwards, still considering the local reference of the figure, that is in direction of the wafer 13, in particular without the device under test 12 onto which the probes rest during the normal operation of the probe head 10.

Furthermore, each contact probe 11 can be provided with a suitable protruding element, as shown in the example of FIG. 1, usually indicated as a stopper 15 and provided projecting starting from a wall of the probe body 11C. In particular, thanks to the shifting of the guides, the contact probe 11, once assembled, has a first side wall ls1 in contact with a wall of a corresponding first upper guide hole 16A of the first upper guide 16 and an opposite second side wall ls2 in contact with a wall of a second upper guide hole 17A of the second upper guide 17. The stopper 15 is thus provided projecting starting from the second side wall ls2 of the contact probe 11, so as to interfere with a lower face F1 of the second upper guide 17 when the contact probe 11 moves upwards, considering the local reference of the figure, that is in direction of the testing apparatus, for example during cleaning operations of the probe head 10, which are usually made by powerful air jets and can imply great vertical displacements of the contact probes 11, the stopper 15 being thus adapted to prevent the movement and sliding of the respective contact probe 11 outside of the probe head 10.

In such case, the upper guide holes 16A and 17A are dimensioned so as to guarantee the passage also of the stopper 15 during the assembly of the probe head 10, as will be explained in the following, the shift between the upper guides 16 and 17 anyway guaranteeing the positioning of the contact probe 11 with the second side wall ls2 resting onto the second upper guide hole 17A above the stopper 15 and thus guaranteeing the contrast of the stopper 15 with the second upper guide 17 above it and the correct retaining of the contact probe 11 inside the probe head 10.

This efficient method of retaining the contact probes 11 by enlargement of the head portions 11B thereof and of interference between the stopper 15 and one of the upper guides, which are shifted so as to bend and deform the probes as requested, entails that the contact probes 11 are assembled inside the probe head 10 starting from the above, that is starting from the side of the board 14 connecting with the testing apparatus, said assembly direction from the above being thus indicated as tester-side (arrow TS in FIG. 1).

At the moment, the assembly of the contact probes in the probe heads with vertical technology occurs mainly in a manual manner; in particular, an operator positions the contact probes so as to centre the guide hole of the first guide, that is the upper guide closer to the board connecting with the testing apparatus, making them go down due to gravity until centring the other guide holes of the other guides until the last one, that is the lower guide closer to the device under test integrated on the wafer, the movement of each contact probe being stopped by the enlarged head portion which does not allow the sliding beyond the guide hole of the first guide, that is the upper guide.

Said assembly of contact probes in a probe head tightly depends on the shape of the probes and on the relative alignment of the guide holes of the guides of the probe head, said characteristics being not controllable and limiting the efficiency of the assembling step in such an incisive way so as to prevent from efficiently automatizing the process.

Also when the specialized operators are possibly assisted by a camera and lightening system, the manual assembly has times and costs connected to the skills of the operators themselves and does not allow large production scales or to face peaks in demand, the period necessary to train a specialized operator being often longer that the period of production peak which would require such specialized operator. In some cases, when the probes have a particularly irregular profile and/or the related guide holes of the guides are very misaligned, the assembly cannot succeed (that is the probes do not manage to be inserted in the guide holes) and this can even cause the breakage of said probes, with further wasting not only of time but also of resources, making the assembly mode of the tester-side type as a whole not efficient.

The problems related to the assembly of the contact probes in the probe holes of the guides of a probe head are furthermore not limited to the moment of assembling the probe head. In fact, once assembled, the probe head can be subjected to wear or malfunctions, in particular regarding the contact probes contained therein.

If, by carrying out the necessary tests, problems are found at a contact probe which should be replaced, the contact head should be disassembled from the testing apparatus and partially disassembled in order to be able to take the defected probe away and replace it with a new probe, still with the already-explained problematic mechanism for extracting and inserting from the above; after replacing the defected probe, the probe head must be reassembled and reconnected to the testing apparatus.

The testing/disassembling/replacing/reassembling operations should be repeated several times as the different contact probes contained in a probe head are tested, which can be several thousand probes. The same operation sequence should be repeated during the lifetime of the probe head in case of malfunction, for example the breakage of a contact probe during the useful lifetime of the probe head.

The technical problem of the present invention is to provide a configuration of a contact probe for a probe head with vertical technology which is capable of simplifying the assembly operations of the probe head but also of periodically testing the operation thereof and replacing of possible defective contact probes, still guaranteeing the correct retaining of the contact probes inside the probe head in any circumstance, thus overcoming the limitations and drawbacks which are still affecting the contact probes and the probe heads made according to the prior art.

### DISCLOSURE OF INVENTION

The idea underlying the present invention is to provide each contact probe with a further connection pin with the lower guide, which is capable of retaining the probe inside the probe head for interfering with said lower guide, without the need to provide a further retaining mechanism such as the enlargement of the head portion thereof or the presence of a stopper projecting from a lateral side thereof, thereby allowing an assembly of the contact probes from the bottom, that is starting from the side of the device under test, commonly indicated as probe-side.

Based on said solution idea, the technical problems is solved by a contact probe having a first end portion which ends with a contact tip configured to abut onto a contact pad of a device under test and a second end portion which ends with a contact head configured to abut onto a contact pad of a board of a testing apparatus, as well as a probe body extended between the first end portion and the second end portion along a longitudinal development axis, said first end portion comprising a first support part, interposed between the probe body and the contact tip, characterized in that the first support part comprises at least one contact pin and a probe length which extend parallel to each other along the longitudinal development axis and are separated by an air gap.

More in particular, the invention comprises the following additional and optional features, taken singularly or, if necessary, in combination.

According to an aspect of the invention, the first support part can further comprise at least one material bridge configured to connect the contact pin and the probe length along a transversal direction that is orthogonal to the longitudinal development axis, said probe length, contact pin and material bridge overall configuring the first support part as U-shaped.

According to another aspect of the invention, the contact tip can be aligned with the contact pin along a further longitudinal axis that is distinct and parallel to the longitudinal development axis of the contact probe.

Furthermore, according to an aspect of the invention, the contact pin can comprise at least one retaining portion at one free end thereof, opposite to an end that is joined to the material bridge, said retaining portion having a transversal diameter that is greater than a transversal diameter of the contact pin outside the retaining portion, transversal diameter meaning a maximum dimension of a transversal section that is orthogonal with respect to the longitudinal development axis, even in case of a non-circular shaped section.

In particular, the retaining portion can further comprise at least one enlarged portion having the transversal diameter that is greater than the transversal diameter of the contact pin, said enlarged portion being adapted to define at least one undercut wall of the retaining portion.

Furthermore, the retaining portion can also comprise at least one longitudinal opening extending along the further longitudinal axis and is configured so as to define at least one pair of portions of the retaining portion capable of approaching and moving away one another if subjected to transversal compressive forces, namely orthogonal to the further longitudinal axis.

According to another aspect of the invention, the second end portion can comprise at least one retaining mechanism configured so as to generate friction with walls of a guide hole when it houses said second end portion, the retaining mechanism preferably comprising a corrugated surface.

Said second end portion can further comprise at least one opening arranged longitudinally along the longitudinal development axis in a second support part of the second end portion, contiguous to the contact head, said at least one opening longitudinally arranged being configured so as to define two opposite portions of the second support part capable of approaching and moving away one another if subjected to transversal compressive forces, namely orthogonal to the longitudinal development axis.

According to an aspect of the invention, the contact probe can also comprise at least one longitudinal slot extending along the probe body and is configured so as to define therein at least one pair of arms, substantially parallel to each other and separated by the longitudinal slot.

The probe body can have a pre-deformed shape with a curvilinear configuration in rest conditions, comprising at least one bend, preferably two bends.

According to another aspect of the invention, the contact probe can further comprise at least one reduced-section portion which forms a bending neck positioned in the probe body in correspondence of one of said first and second end portions.

The technical problem is also solved by a probe head for testing the functionality of a device under test comprising a single upper guide provided with upper guide holes and a single lower guide provided with lower guide holes for housing a plurality of contact probes, said contact probes being made as indicated above and said lower guide holes comprising first lower guide holes adapted to house the probe lengths of the contact probes and second lower guide holes adapted to house the contact pins of the contact probes.

According to an aspect of the invention, the second lower guide holes can have a transversal diameter that is equal to or lower than a transversal diameter of a retaining portion of the contact pins, these diameters preferably differing by 0 to 10%.

According to another aspect of the invention, the probe head can comprise first contact probes and second contact probes having respective contact pins spaced from respective probe lengths by a first distance and by a second distance, respectively, said first and second distances being different from each other so as to spatially redistribute contact pads of an interface board whereonto respective contact heads of said first contact probes and second contact probes abut with respect to contact pads of a device under test whereonto respective contact tips of said first contact probes and second contact probes abut.

According to still another aspect of the invention, the probe head can further comprise at least one upper frame, associated with the single upper guide and provided with respective upper openings adapted to house the contact probes and at least one lower frame, associated with the single lower guide and provided with respective lower openings for housing the contact probes.

Finally, the contact probes can comprise transversal material bridges adapted to connect the probe lengths and the contact pins positioned in rest conditions at a distance from the lower guide that is greater by a maximum overtravel value of the contact probes, said overtravel being a displacement of the contact tips of the contact probes along the longitudinal development axis when the contact probes are in pressing contact onto contact pads of a device under test.

The features and advantages of the contact probe and the probe head according to the present invention will result from the description, made herein in the following, of embodiments given by way of an indicative and non-limiting example with reference to the attached drawings.

### BRIEF DESCRIPTION OF DRAWINGS

In Said Drawings:

FIG. 1 schematically shows a frontal view of a probe head made according to the prior art;

FIGS. 2A and 2B show respective frontal views of embodiments of a contact probe according to the present invention;

FIGS. 3A and 3B show respective frontal views of alternative embodiments of the contact probe according to the present invention;

FIG. 4 shows a frontal view of a preferred embodiment of the contact probe according to the present invention;

FIGS. 5A and 5B show respective enlarged views of details of the embodiment of FIG. 4;

FIG. 6 shows a fontal view of a probe head according to the present invention, comprising contact probes according to the embodiment of FIG. 4;

FIGS. 7A and 7B show respective frontal views of a probe head according to the present invention in different operation conditions thereof;

FIGS. 8A and 8B show respective top and frontal views of a possible configuration of contact probes made according to the embodiment of FIG. 4.

### MODES FOR CARRYING OUT THE INVENTION

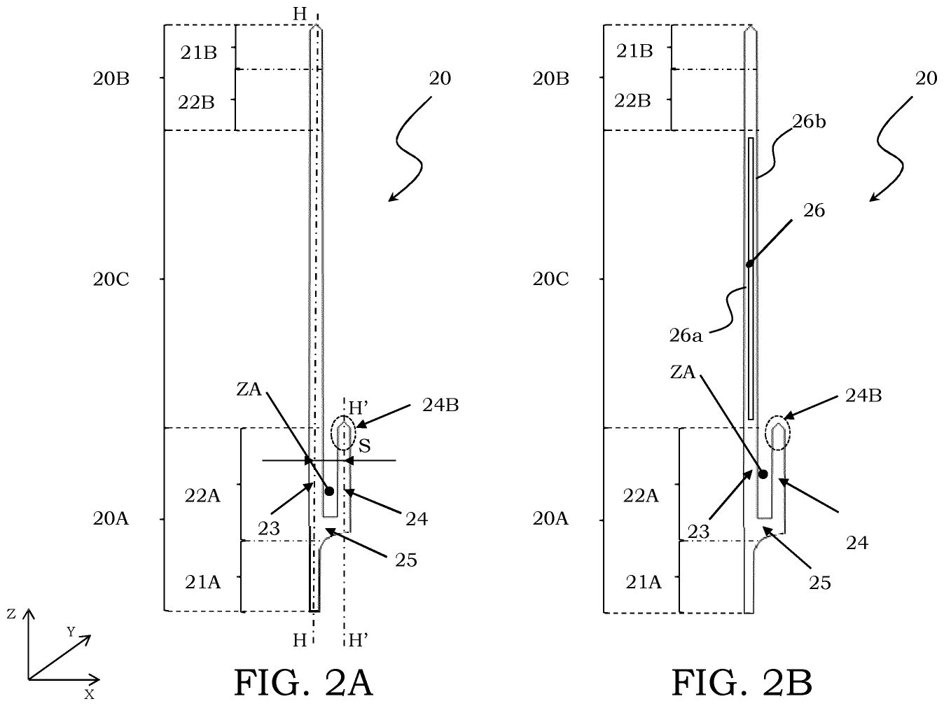

With reference to said figures, and in particular to FIGS. 2A and 2B, a contact probe made according to the present invention, overall indicated with 20, is described.

It should be noted that the figures represent schematic views and are not drawn to scale, but instead they are drawn so as to emphasize the important features of the invention. Moreover, in the figures, different pieces are depicted in a schematic manner, their shape may vary depending on the desired application. Also, particular features shown in a figure in relation to an embodiment can also be used in one or more of the embodiments shown in the other figures.

Furthermore, structurally and functionally equal elements in the different embodiments, which are shown in the various figures and described in the following, are indicated with the same alphanumeric references.

In the following description, relative terms such as “over”, “under”, “upwards”, “downwards” will be used referring to the illustrations of the probes and probe heads given in the figures only for simplifying the exposition thereof.

Finally, indications of particular geometries (circular, rectangular) or of the arrangement of the elements (parallel, orthogonal, contiguous) as well as the term “substantially” are to be understood as always relating to physical elements and not geometrically abstract elements, and they must then always take into account the tolerances introduced by the passage from a pure mathematic/geometric world to the real world.

The contact probe 20 comprises at least one first end portion 20A which ends with a contact end adapted to abut onto a contact pad of a device under test and indicated as contact tip 21A; the first end portion 20A comprises a first support part 22A adjacent to said contact tip 21A and adapted to be housed in a respective guide hole of a guide of a probe head comprising the contact probe 20, in particular a guide hole of a lower guide, that is a guide positioned close to the device under test. In other words, the first end portion 20A comprises a first section and a second section, the first section being housed at least partially in a guide hole of a guide, in particular a lower guide, of a probe head in which the probe is inserted during the testing steps of a respective device under test, said first section substantially comprising the first support part 22A, and the second section protruding from said guide towards the device under test and being adapted to realise the connection with the pads thereof through pressing contact thereon, said second section substantially comprising the contact tip 21A.

Furthermore, the contact probe 20 comprises a second end portion 20B which ends with a contact end adapted to abut onto a contact pad of an interface board with a testing apparatus and indicated as contact head 21B; the second end portion 20B comprises a second support part 22B, contiguous to the contact head 21B and adapted to be housed in a guide hole of a guide of the probe head which comprises the contact probe 20, in particular a guide hole of an upper guide, namely a guide positioned close to the interface board with the testing apparatus. In other words, the second end portion 20B in turn comprises a first section and a second section, the first section being housed at least partially in a guide hole of a guide, in particular an upper guide, of a probe head in which the probe is inserted during the testing steps of a respective device under test and the second section substantially comprising the second support part 22B, and the second section protruding from said guide towards the interface board of the testing apparatus and being adapted to realise the connection with its pads through pressing contact thereon, said second section substantially comprising the contact head 21B.

Finally, the contact probe 20 comprises a probe body 20C, substantially rod-shaped and extended between the first end portion 20A and the second end portion 20B, according to a longitudinal development axis HH of the contact probe 20, substantially in the direction z of the local reference of the figure. In the following of the description, the term longitudinal will be thus used to indicate elements arranged according to a direction or a plane parallel to the longitudinal development axis HH.

Suitably, according to the present invention, the first end portion 20A further comprises a contact pin 24 which extends parallel to a probe length 23 comprised in the first support part 22A of the contact probe 20, said probe length 23 being separated by the contact pin 24 by an air gap ZA; in particular, the contact pin 24 extends along a further longitudinal axis H′H′, which is distinct and parallel to the longitudinal development axis HH of the contact probe 20, and thus of the probe length 23, and separated therefrom by a distance S. Thereby, the first support part 22A comprises the probe length 23 and the contact pin 24, which are parallel to each other and separated by the air gap ZA.

Suitably, the probe length 23 and the contact pin 24 are connected to each other and to the contact tip 21A by a material bridge 25 which extends between the air gap ZA, the probe length 23, the contact pin 24 and the material bridge 25 thus defining the first part 22A of the contact probe 20 according to a U-shape. Thereby, the contact probe 20 develops along the longitudinal development axis HH between the contact head 21B and the contact tip 21A and comprises therebetween the first support part 22A including the probe length 23, the contact pin 24 and the material bridge 25 according to a U-shape.

In particular, in the embodiment shown in FIGS. 2A and 2B, the contact tip 21A is aligned with the probe length 23 along the longitudinal development axis HH, while the contact pin 24 is shifted with respect to the probe length 23 and the probe body 20C by a distance equal to the length of the material bridge 25. It is possible to realise the contact tip 21A in a tapered shape, namely with a transversal section, that is orthogonal to the longitudinal development axis HH, gradually decreasing towards the pad of the device under test onto which said contact tip 21A is intended to abut, so as to reduce the actual abutting area on said pad and make the contact probe 20 adapted for applications with pads with particularly reduced sizes.

Also the contact pin 24 is adapted to be housed at least partially in an additional guide hole of a guide of a probe head comprising the contact probe 20, in particular an additional guide hole of a lower guide wherein lower guide holes at least partially house the probe lengths 23.

Suitably, the contact pin 24 also comprises at least one retaining portion 24B. As will be clarified below, said retaining portion 24B develops substantially longitudinally and is adapted to retain the contact probe 20 inside a corresponding probe head, hindering the movement of the contact pin 24 outside the additional guide hole which houses it in a guide of said probe head, in particular a movement towards the device under test when the probe head is moved away from the wafer comprising said device under test, for example at the end of a testing operation, or during cleaning operations made by air jets, the retaining portion 24B protruding from the guide in opposite direction with respect to the device under test. Suitably, the retaining portion 24B is made in correspondence of a free end of the contact pin 24, namely an end opposite to an end that is joined to the material bridge 25, said free end being the one closer to the interface board with the testing apparatus, while the joined end is the one closer to the device under test.

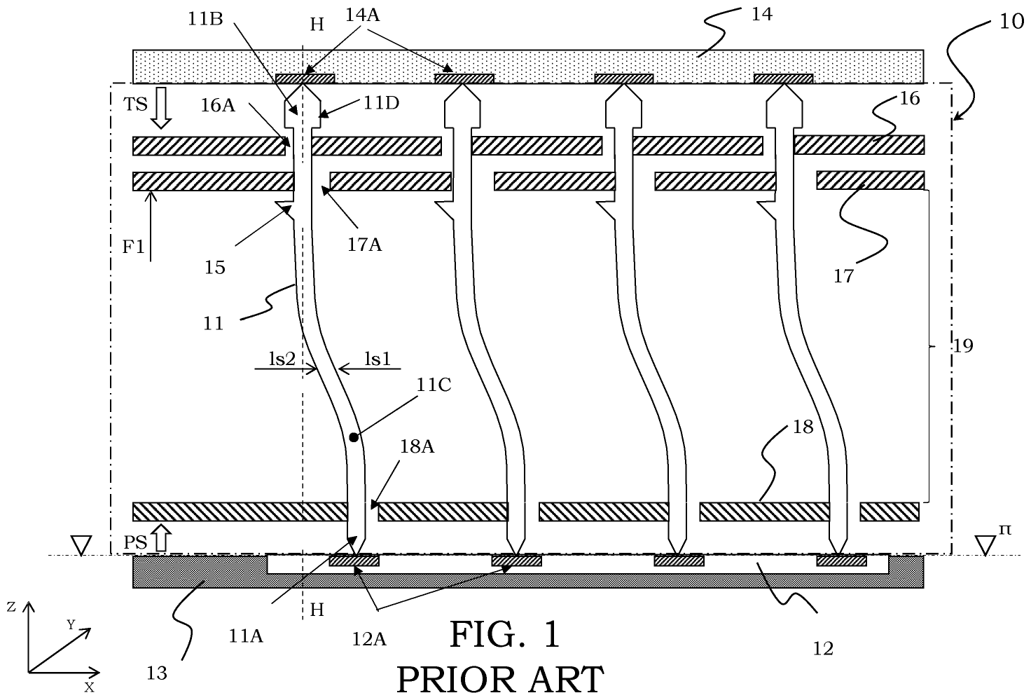

The contact probe 20 configured in this way is thereby adapted to be assembled inside a probe head starting from the side corresponding to the device under test, namely the so-called probe-side, no enlarged or protruding portion being provided at the second end portion 20B thereof, for example in the form of a head enlarged portion, or along the probe body 20C, for example in the form of a stopper, the retaining of the contact probe 20 in the corresponding probe head being guaranteed by the retaining portion 24B of the contact pin 24 thereof. In other words, the assembly of the contact probes 20 made in this way occurs in a opposite way with respect to the known solutions, namely from the probe side PS rather than from the tester side TS, according to the arrows depicted in FIG. 1, said assembly being allowed because of the absence of an enlarged portion at the head portion and/or a protruding portion such as a stopper positioned along the probe body.

In an alternative embodiment shown in FIG. 2B, the contact probe 20 also comprises at least one longitudinal slot 26 which extends along the probe body 20C and defines therein at least one pair of arms 26a, 26b, which are substantially parallel to each other and separated by the slot 26, capable of increasing the elasticity of the contact probe 20 as a whole, allowing to reduce the longitudinal extension and making it suitable also for the high frequency or RF applications, when the contact probe 20 should have a reduced overall length with respect to the applications with non-RF signals.

In the embodiment shown FIG. 2B, the arms 26a and 26b have equal diameters or transversal dimensions but it is obviously possible to make arms having different transversal dimensions, obtained for example by a slot 26 which is positioned not centrally with respect to the transversal extension of the probe body 20C.

It is also possible to define a plurality of arms in the probe body 20C by a corresponding plurality of longitudinal slots made therein, dimensioned and spaced from each other according to the applicative needs of the contact probe 20 which is desired to be obtained.

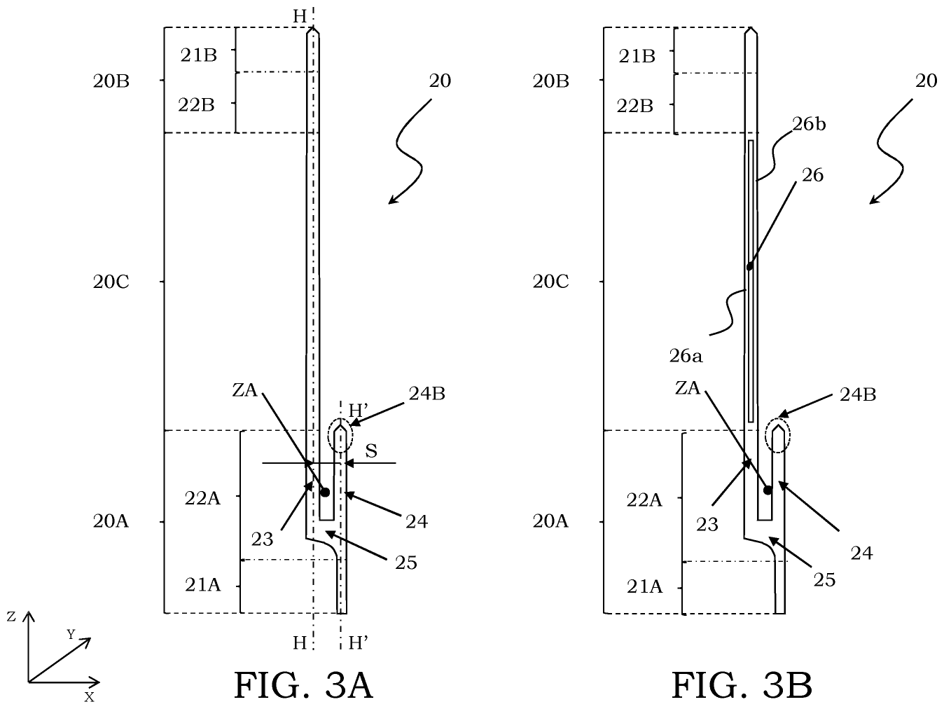

According to a preferred embodiment, shown in FIGS. 3A and 3B, the contact tip 21A is contiguous and aligned to the contact pin 24, namely said contact tip 21A and said contact pin 24 are arranged in sequence with respect to each other along the further longitudinal axis H′H′. Thereby, the material bridge 25, adapted to connect the probe length 23 with the contact pin 24, realises a decentring of the contact tip 21A protruding with respect to the probe length 23 and thus to the probe body 20C and the contact head 21B and allows to obtain an enlargement of the distance between contact tip 21A and contact head 21B with respect to the longitudinal development axis HH of the contact probe 20.

The decentring or misalignment value between contact head 21B and the contact tip 21A is thus determined by the length S of the material bridge 25, also corresponding to the distance between longitudinal development axis HH of the probe length 23 and thus of the contact head 21B and the further longitudinal development axis H′H′ of the contact pin 24 and thus of the contact tip 21A.

Furthermore, in the embodiment of FIG. 3B, the contact probe 20 comprises a slot 26 adapted to define at least one pair of arms 26a, 26b in the probe body 20C, so as to make it suitable for the RF applications.

The contact probe 20 with contact tip 21A misaligned with respect to the contact head 21B, as shown in FIGS. 3A and 3B, is advantageously self-centred with respect to the pads of the device under test, the contact tip 21A thereof being automatically aligned thanks to the contact pin 24 which is housed in the additional guide hole. More in particular, it is possible to realise the additional guide holes for housing the contact pins 24 so as to be centred with respect to the contact pads of the device under test. It is thus possible to avoid the known centring process, particularly used for the known cantilever probe heads, which is a time-consuming process, especially in case of probe heads with a very large number of probes.

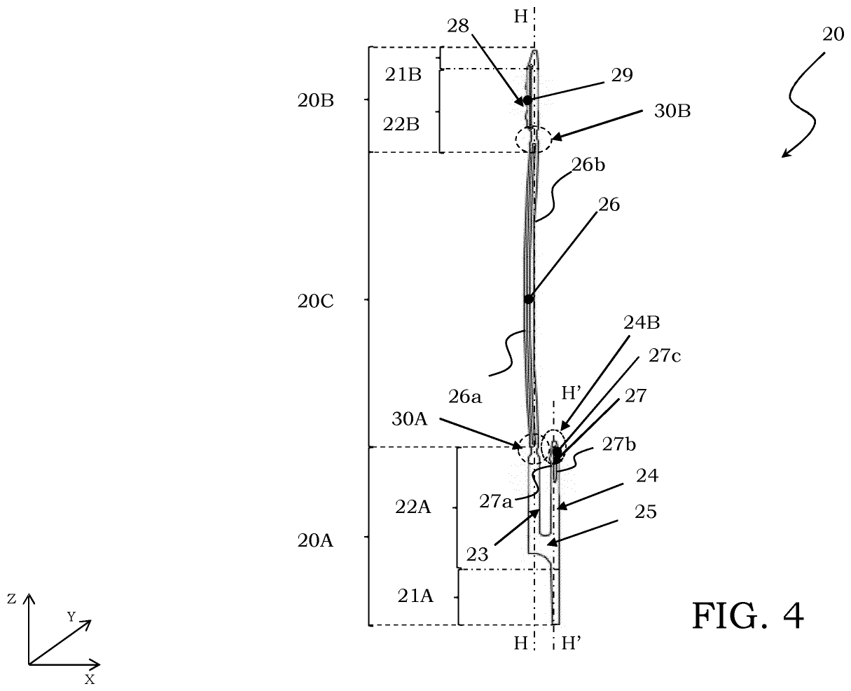

More in particular, according to a preferred alternative embodiment shown in FIG. 4, the probe body 20C has a pre-deformed shape, namely a curvilinear configuration already in rest conditions, when the contact probe 20 is not in pressing contact onto a contact pad of a device under test. In the example shown in FIG. 4, the probe body 20C has a curvilinear form with one bend, namely arc-shaped. Suitably, the one-bend shape of the contact probe 20, in particular of the probe body 20C thereof, is thus also present in non-operative conditions of the probe, namely before it bends and deforms during the testing, the one-bend pre-deformation of the probe body 20C guaranteeing that the contact probes 20 bend in a same desired direction during the testing.

Although not shown in the figures, it is also possible to realise the probe body 20C such that it has a pre-deformed shape with a two-bend shape, the two bends being arranged as opposite with respect to the longitudinal development direction z, substantially S-shaped. Said pre-deformed S-shape is particularly adapted to guarantee the correct operation of the contact probe 20 also when its overall dimensions are reduced, for example in case of RF applications.

Suitably, the retaining portion 24B of the contact pin 24 of the contact probe 20 comprises a longitudinal opening 27, which extends along the further longitudinal axis H′H′ and is adapted to define two opposite portions 27a, 27b in the retaining portion 24B capable of approaching and moving away if subjected to transversal compressive forces, namely orthogonal with respect to the further longitudinal axis H′H′ along which the contact pin 24 develops, said transversal compressive forces being thus applied according to the direction x of the local reference of FIG. 4. In the following description, the term transversal is used to indicate elements arranged according to a direction or plane orthogonal to the longitudinal development axis HH and thus to the further longitudinal axis H′H′.

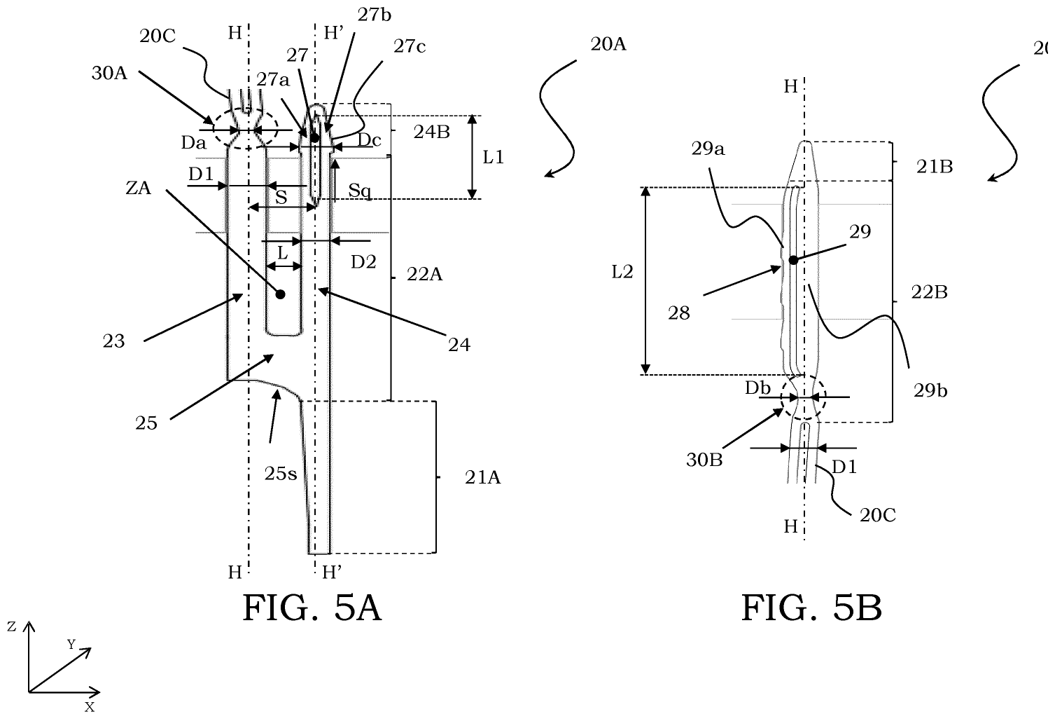

More in particular, as shown in the enlargement of FIG. 5A, the longitudinal opening 27 extends for a length L1 which varies between 100 μm and 300 μm inside the contact pin 24 and is transversally dimensioned so as to enlarge the retaining portion 24B up to analogous and slightly higher transversal dimensions of a corresponding further guide hole made in a guide of a probe head which houses the contact probe 20, in particular a lower guide, so as to prevent or at least hinder the movement of the contact probe 20, once inserted in the probe head, downwards along the direction z of the local reference of the figure, namely towards the device under test when the probe head which comprises said contact probe 20 is removed from the device under test once subjected to the testing, in particular in case of an undesired adhesion of the contact tip 21A on a corresponding contact pad of the device under test, said adhesion making the contact probe 20 to slide downwards, namely towards the device under test, when the corresponding probe head is moved away from the device under test after the testing.

Thereby, the contact pin 24 provided with retaining portion 24B works as retaining element of the contact probe 20 inside a corresponding probe head. The presence of the longitudinal opening 27 configures the retaining portion 24B as elastic retaining means.

More in particular, in the embodiment shown in FIG. 4 and in the enlargement of FIG. 5A, the longitudinal opening 27 is positioned centrally with respect to the retaining portion 24B, so as to define the two opposite portions 27a, 27b which are substantially equal. The retaining portion 24B configured in this way substantially acts as an elastic stopper which contrasts the passage of the contact pin 24 through the further guide hole without preventing the passage thereof during the assembly operations of the contact probe 20 in the probe head, as well as the extraction thereof by an operator during possible maintenance operations which require, for example, to remove and replace the contact probe 20, still guaranteeing a correct retaining also when the probe head housing it is not in pressing contact onto a device under test, said retaining portion 24B being capable of efficiently contrasting the movement of the contact probe 20 due to gravity or other transversal forces, such as during cleaning operations normally made by air jets.

Suitably, the retaining portion 24B of the contact pin 24 also comprises an enlarged portion 27c, namely having a transversal diameter Dc that is greater than a transversal diameter of a corresponding additional guide hole which houses the contact pin 24, transversal diameter meaning herein and the following a maximum dimension of a transversal section, namely orthogonal with respect to the further longitudinal axis H′H′, of the retaining portion 24B, also in case of a non-circular shaped section. Preferably, the diameter Dc of the enlarged portion 27c is equal to 102-110% of the transversal diameter of the corresponding additional guide hole which houses the contact pin 24.

Thereby, the enlarged portion 27c defines at least one undercut wall Sq of the retaining portion 24B adapted to abut onto a guide comprising the additional guide hole which houses the contact pin 24, so as to further guarantee the retaining of the contact pin 24 in said additional guide hole.

In particular, the enlarged portion 27c projects with respect to the transversal dimensions of the additional guide hole of a quantity equal to or comparable with the transversal dimension of the longitudinal opening 27, comparable meaning, here and in the following, that the transversal dimensions differ by +1-5%. Thereby, it is anyway possible to allow the retaining portion 24B and in particular the enlarged portion 27c thereof to pass inside the additional guide hole which houses the contact pin 24 during the assembly operations, approaching the opposite portions 27a, 27b so as to eliminate the space defined by the longitudinal opening 27 inside the retaining portion 24B.

Furthermore, in the embodiment shown in FIG. 4 and in the enlargement of FIG. 5A, the material bridge 25 is made so at to comprise a rounded side 25s, preferably circle arc-shaped, connecting the contact tip 21A and the probe length 23, made so as to face the device under test, said arc-shaped connection reducing the stress generated in the material bridge 25 during the operation of the contact probe 20, when the contact tip 21A thereof is in pressing contact onto a pad of a device under test.

Suitably, also the second end portion 20B of the contact probe 20 can be provided with a retaining mechanism 28, which is shown more in detail in FIG. 5B, configured so as to cause friction in correspondence of walls of a guide hole in which the contact probe 20, in particular the second end portion 20B, is housed. In the embodiment shown in FIGS. 4 and 5B, said retaining mechanism 28 comprises at least one corrugated surface capable of contrasting and generating friction with the walls of a guide hole of a corresponding guide of a probe head which houses the contact probe 20, in particular a guide hole of an upper guide of said probe head. The retaining mechanism 28 further contributes to maintain the contact probe 20 inside the probe head thanks to an additional friction, which is obtained in correspondence of the upper guide and adds up to the retainment made thanks to the retaining portion 24B of the contact pin 24 in correspondence of the lower guide.

Obviously, the retaining mechanism 28 should be configured so as to not completely prevent the movement of the contact probe 20, namely the stuck of the same in the guide hole of the upper guide, so as not to hinder the proper operation thereof, said contact probe 20 being anyway intended to bend and slide inside the guide holes which houses it according to the well-known so-called bulking operation.

In other words, the retaining mechanism 28 of the contact probe 20 in correspondence of the guide hole of the upper guide should not be so strong such as to prevent the contact 21B of the contact probe 20 to displace and abut onto a corresponding contact pad of an interface board with the testing apparatus connected to the probe head including said probe, namely should not prevent the current working of the contact probe 20 during the testing operations carried out by the probe head which comprises it.

Furthermore, the second end portion 20B also comprises at least one opening 29 arranged longitudinally in the second part 22B thereof, so as to define two opposite portions 29a, 29b of said second part 22B and giving it an elasticity which allows to realise said second part 22B with a transversal diameter comparable to the one of the corresponding guide hole which houses the contact probe 20, in particular the second part 22B of the second end portion 20B, facilitating the creation of friction thanks to the retaining mechanism 28 in sliding contact with the walls of said guide hole in which the contact probe 20 is substantially housed without clearance. In particular, also the opposite portions 29a, 29b of said second part 22B are capable of approaching and moving away one another if subjected to transversal compressive forces.

Suitably, as schematically shown in FIGS. 4 and 5A, the contact probe 20 further comprises at least one bending neck 30A, positioned in correspondence of one of the ends of the probe body 20C, preferably, as in the depicted example, at the end of the probe body 20C in correspondence of the first end portion 20A. More in particular, said bending neck 30A comprises a reduced-section portion of the probe body 20C, preferably having a section diameter Da reduced by 30-60% with respect to the diameter D1 of the section of the probe body 20C, more preferably equal to 50% of said diameter D1.

In the embodiment shown in FIG. 4 and in the enlargement of FIG. 5B, the contact probe 20 comprises a further bending neck 30B positioned in correspondence of the other end of the probe body 20C, at the end of the probe body 20C in correspondence of the second end portion 20B, said further bending neck 30B being still made by a reduced-section portion, preferably having a section with diameter Db reduced by 30-60% with respect to the diameter D1 of the section of the probe body 20C, more preferably equal to 50% of said diameter D1.

In the embodiment shown in FIG. 4, the bending necks 30A and 30B are preferably arranged at the centre of the contact probe 20, in a concentric way with respect to the probe body 20C, along the longitudinal development direction z and are obtained by removing material symmetrically from the probe body 20C, in particular starting from opposite side walls of said probe body 20C or annularly along all the contour of the probe body 20C. Furthermore, in the embodiment shown in FIGS. 4, 5A and 5B, the bending necks 30A and 30B are substantially equal to each other and are both placed concentrically with respect to the probe body 20C. It is obviously possible to make the contact probe 20 so as to comprise bending necks 30A and 30B different from each other, one or both being arranged in a non-concentric way with respect to the probe body 20C, for example made by asymmetrically removing material from the probe body 20C.

It can be immediately verified that the presence of the bending necks 30A and 30B, in particular in correspondence of the ends of the arms 26a, 26b and thus of the slot 26 being realised in the body 20C, which are known to be areas more subjected to breakages, is capable of reducing the stress to which said arms 26a, 26b are subjected, in particular during the testing operations, that is when the contact probe 20 bends and deforms due to its abutment onto the contact pads of the device under test.

Furthermore, thanks to their central position, said bending necks 30A and 30B do not negatively affect the bending mechanism of the contact probe 20 and the scrub of the contact tip 21A thereof.

Preferably, the contact pin 24 of the first end portion 20A has a transversal diameter D2 that is equal to or lower than the diameter D1 of the section of the probe body 20C.

Although the embodiment shown in FIG. 4 and in the enlargements of FIGS. 5A and 5B shows a contact probe 20 provided with the retaining mechanism 28 and with two bending necks 30A, 30B, it is also possible to make it so as to comprise only the two bending necks 30A and 30B, or only one bending neck 30A or 30B, or only the retaining mechanism 28, or still the retaining mechanism 28 and only one bending neck 30A or 30B. Furthermore, although not shown in the figures, the contact probe 20 could not comprise the slot 26 but could comprise the retaining mechanism 28 and/or one or two bending necks 30A, 30B. In other words, although not shown in the figures, the characteristics related to the presence of the slot 26, the retaining mechanism 28 and the bending necks 30A and/or 30B can be separately used in a contact probe 20 according to the present invention. Furthermore, also the characteristics related to the pre-deformation of the probe body 20C and the presence of the slot 26 are separately usable.

The present invention also refers to a probe head of the type with vertical probes, which can advantageously comprise only a pair of guides provided with guide holes of a plurality of contact probes made as previously explained.

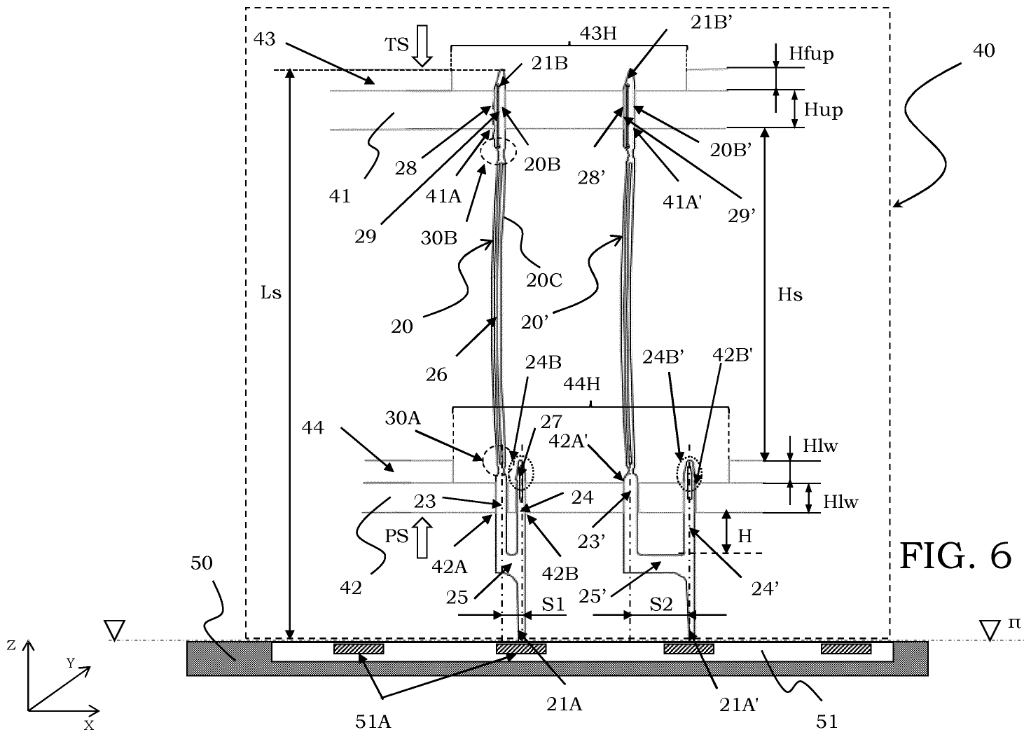

More in particular, referring to FIG. 6, a probe head 40 comprising a plurality of probes made according to the embodiment shown in FIG. 4, namely provided with a contact pin 24 aligned with the contact tip 21A, is described. In the embodiment of FIG. 6, the contact probes 20 comprise a probe body 20C that is pre-deformed and provided with a slot 26, as well as a retaining portion 24B of the contact pin 24 provided with a longitudinal opening 27, the second end portion 20B being provided with a friction retaining mechanism 28 and a further opening 29 as well as bending necks 30A and 30B but it is obviously possible to make the probe head 40 using contact probes 20 which are not comprising one or more of said features.

The probe head 40 comprises a first plate-shaped guide or upper guide 41, commonly indicated as upper die, provided with suitable upper guide holes 41A for housing the contact probes 20, as well as a second plate-shaped guide or lower guide 42, commonly indicated as lower die, also provided with suitable first lower guide holes 42A for housing the contact probes 20 in correspondence of the probe length 23. Suitably, the lower guide 42 also comprises second lower guide holes 42B for housing the contact probes 20 in correspondence of the contact pin 24.

Suitably, the second lower guide holes 42B have a transversal diameter that is equal to or lower than the transversal diameter Dc of the enlarged portions 27c of the contact pins 24, said diameters preferably differing by 0 to 10%.

As seen in relation to the prior art, the upper guide 41 and the lower guide 42 are spaced from each other so as to define therebetween an air gap in which the contact probes 20 are free of bending during the pressing contact of the contact tips 21A thereof onto a contact pad 51A of a device under test 51 integrated on a semiconductor wafer 50, the corresponding contact heads 21B abutting onto contact pads of an interface board with the testing apparatus (not shown), which the probe head 30 forms a terminal element thereof. As seen in relation to the prior art, said interface board can be a so-called space transformer.

Suitably, the probe head 40 also comprises an upper frame 43, associated with the upper guide 41 and provided with respective upper openings 43H adapted to house the contact probes 20 and a lower frame 44, associated to the lower guide 42 and equally provided with lower openings 44H for housing the contact probes 20. Preferably, the upper frame 43 and the lower frame 44 are ceramic or metallic elements.

More in particular, the upper frame 43 is fixedly connected to the upper guide 41 thanks to the use of connection elements such as screws, pins or adhesive films and analogously the lower frame 44 is fixedly connected to the lower guide 42 still by connection elements such as screws, pins or adhesive films. The upper frame 43 and the lower frame 44 are thereby integral with the upper guide 41 and the lower guide 42, respectively, and act as structural reinforcement elements thereof, as well as alignment means of the contact probes 20 while assembling the probe head 40. It is thereby possible to use guides, preferably ceramic, of reduced thicknesses, which facilitate the sliding of the contact probes 20 inside the guide holes thereof. Suitably, the presence and in particular the arrangement of the second lower guide holes 42B for housing the contact pins 24 also guarantee a centring of the contact tips 21A with respect to the contact pads 51A of the device under test 51.

The upper guide 41 and the lower guide 42 as well as the upper frame 43 and the lower frame 44 are parallel to each other and extend along a reference plane n, which is the same along which also the semiconductor wafer 50 and the device under test 51 as well as the interface board of the testing apparatus (not shown) develop. It is underlined that, here and in other parts of the text, the reference to elements which are planar or develop on a plane should be intended as in the physical world and not in an abstract geometric sense, therefore taking into account the imperfections of real objects with respect to the perfection of the pure geometrical ones.

More in particular, the lower guide 42 and the upper guide 41 have respective thicknesses Hlw, Hup along the longitudinal development direction z with values which vary from 0.200 mm to 0.450 mm, preferably equal to 0.250 mm for the lower guide 42 and 0.320 mm for the upper guide 41 while the upper frame 43 and the lower frame 44 have respective thicknesses Hfup, Hflw, which vary from 0.150 mm to 0.200 mm, preferably equal to each other and equal to 0.180 mm.

It is also possible to configure the guides and frames such that the assembly of the upper guide 41 and the upper frame 43 has a thickness comparable, preferably equal, to the assembly of the lower guide 42 and of the lower frame 44, so as to guarantee a symmetry of the dynamic and elastic performance of the contact probe 20 and the probe head 40 as a whole, comparable meaning that there is a difference of ±20% between the two overall thickness values.

In a preferred embodiment, the upper guide 41 and the lower frame 44 are placed at a distance Hs along the axis z comprised between 2.000 mm and 3.000 mm, preferably equal to 2.750 mm, so as to keep the overall thickness of the probe head 40 limited. Furthermore, it is underlined that the contact probes 20 comprised in the probe head 40 can suitably have reduced dimensions, in particular overall lengths Ls lower than 5 mm, preferably lower than 4 mm, thus making them suitable for high frequency or RF applications.

As previously explained, the contact probe 20 can be advantageously assembled inside the probe head 40 from the bottom, that is from the probe side, indicated by the arrow PS in FIG. 6. Suitably, therefore, in case of problems found during the operation of the probe head 40 connected to a malfunction of a contact probe 20, for example in case of breakage of said probe, it is not needed to disassemble and reassemble the retaining mechanics of the contact probes 20 to access them, operation which can imply the disassemble of more than 50 screws and force to subsequent re-planarization operations; the operator is in fact capable to extract from the bottom said malfunctioning contact probe 20, simply by applying a force capable of overcoming only the retainment made by the retaining portion 24B of the corresponding contact pin 24, which is in particular enough to make the longitudinal opening 27 collapse so as to reduce the overall diameter of said retaining portion 24B and allow the passage through the respective second lower guide hole 42B within which the contact pin 24 is housed in the lower guide 42.

The probe head 40 could also comprise contact probes with different configurations from each other. In particular, as shown in FIG. 6 only by way of example, the probe head 40 comprises a first contact probe 20 having a contact pin 24 aligned to the contact tip 21A and spaced from the probe length 23 by a first distance S1, corresponding to the length of the material bridge 25 which connects the probe length 23 and the contact pin 24. Said first distance S1 is more particularly calculated as distance between the longitudinal development axes HH and H′H′ of the probe length 23 and the contact pin 24, respectively, and corresponds to a distance between the first lower guide hole 42A and the second lower guide hole 42B, which are realised in the lower guide 42 and which house said elements of the first contact probe 20.

The probe head 40 also comprises a second contact probe 20′ having a contact pin 24′ aligned with the contact tip 21A′ and spaced from the probe length 23′ of a second distance S2, corresponding to the length of the material bridge 25′ which connects the probe length 23′ and the contact pin 24′. Said second distance S2 is more particularly calculated as distance between the longitudinal development axes of the probe length 23′ and the contact pin 24′, respectively, and corresponds to a distance between the first lower guide hole 42A′ and the second lower guide hole 42B′ which are realised in the lower guide 42 and which house said elements of the second contact probe 20′. Suitably, the second distance S2 is different, for example greater, with respect to the first distance S1.

Thereby, thanks to the usage of contact probes 20, 20′ provided with contact pins 24, 24′ and contact tips 21A, 21A′ aligned thereto and displaced with respect to the probe length 23, 23′ and thus to the probe body, the probe head 40 realises a spatial transformation at the lower guide 42, which thus also acts as space transformer.

The first contact probe 20 and the second contact probe 20′ furthermore have respective second end portions 20B, 20B′ housed in corresponding upper guide holes 41A, 41A′ made in the upper guide 41.

More in particular, the contact heads 21B, 21B′ of the first contact probe 20 and of the second contact probe 20′ emerge from the upper guide 41 in direction of the testing apparatus (not shown) inside the upper openings 43H made in the upper frame 43; analogously, the retaining portions 24B, 24B′ of the contact pins 24, 24′ of the first contact probe 20 and of the second contact probe 20′ emerge from the lower guide 42 in direction of the upper guide 41, namely still in direction of the testing apparatus, inside lower openings 44H of the lower frame 44.

Suitably, as previously seen, the contact probes 20, 20′ could also comprise, in correspondence of the second end portion 20B, 20B′ thereof, at least one retaining mechanism 28, 28′, in the form, for example, of a corrugated surface or anyway provided with reliefs or bumps, capable of creating friction with the respective upper guide hole 41A, 41A′, so as to hinder a movement of the contact probe 20, 20′ towards the device under test 51. Each second end portion 20B, 20B′ could further comprise an opening, so as to configure an elastic retaining mechanism for the respective contact probe 20, 20′.

Although not shown in the figures, it is also possible to make the probe head 40 so as to comprise contact probes 20 provided with contact pins 24 as described above and vertical contact probes made according to the prior art.

Furthermore advantageously, the contact probes 20, 20′ comprised in the probe head 40 are configured such that the material bridges 25, 25′ thereof are positioned at a distance H of the lower guide 42 in rest conditions, namely by touching the respective contact tips 21A, 21A′ on the contact pads 51A of the device under test 51. The distance H is thus chosen so as to be greater than a maximum value of the so-called overtravel, namely the movement which the contact probe 20, 20′ performs upwards, considering the local reference of the figures, namely in direction of the testing apparatus, during the testing operations, so as not to affect the correct working of the probe head 40 as a whole.

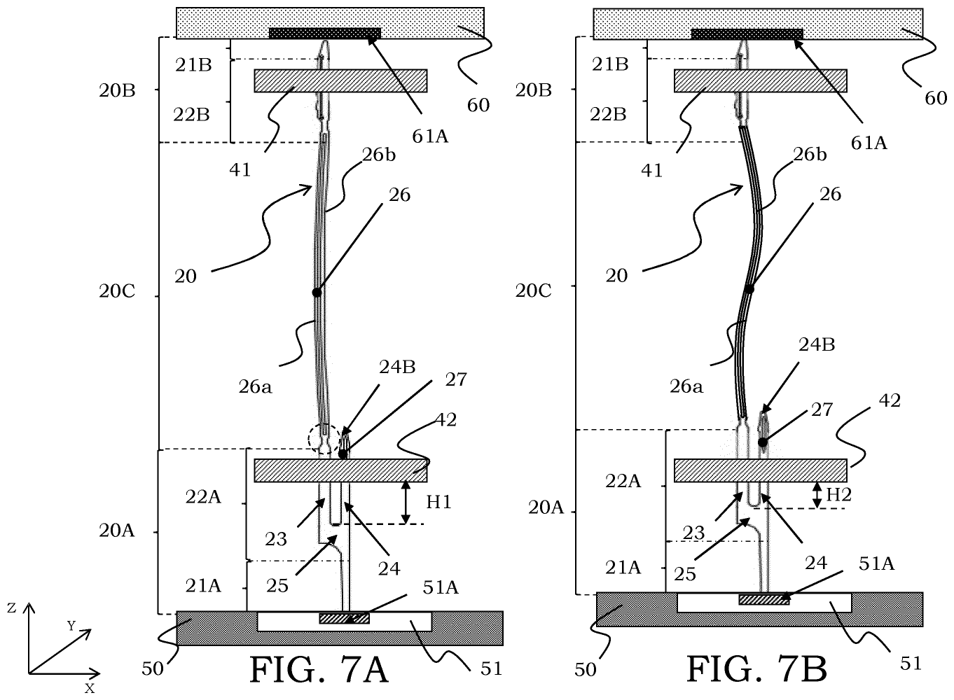

More in particular, as shown in FIG. 7A, in which only one contact probe 20 is represented for the sake of simplicity of illustration, said contact probe 20 is in rest conditions, with the contact tip 21A abutting onto the contact pad 51A of the device under test 51 and the contact head 21B abutting onto a corresponding contact pad 61A of an interface board 60 with the testing apparatus; the contact probe 20 comprises the material bridge 25 placed at a distance H, taken according to the axis z of figure, namely in the direction of the longitudinal development axis HH, having a first value H1. In working conditions, as shown in FIG. 7B, when the contact tip 21A is in pressing contact onto the contact pad 51A of the device under test 50, said contact tip 21A is pushed upwards, namely towards the testing apparatus and the probe body 20C thereof deforms inside the air gap defined between the upper guide 41 and the lower guide 42 of the probe head 40; in these conditions, the distance H between the material bridge 25 and the lower guide 42 decreases up to a value H2, being anyway capable of avoiding any contact between probes 20 and lower guide 42.

Typical values of the distance H in rest conditions (H1) are 250 μm to 450 μm, preferably 350 μm, with overtravel values lower than 100 μm, preferably equal to 80 μm, so as to guarantee a value of the distance H in working conditions (H2) which is anyway greater than 150 μm and avoid any possible contact risk between the material bridges 25 of the contact probes 20 and the lower guide 42 of the probe head 40 which houses them.

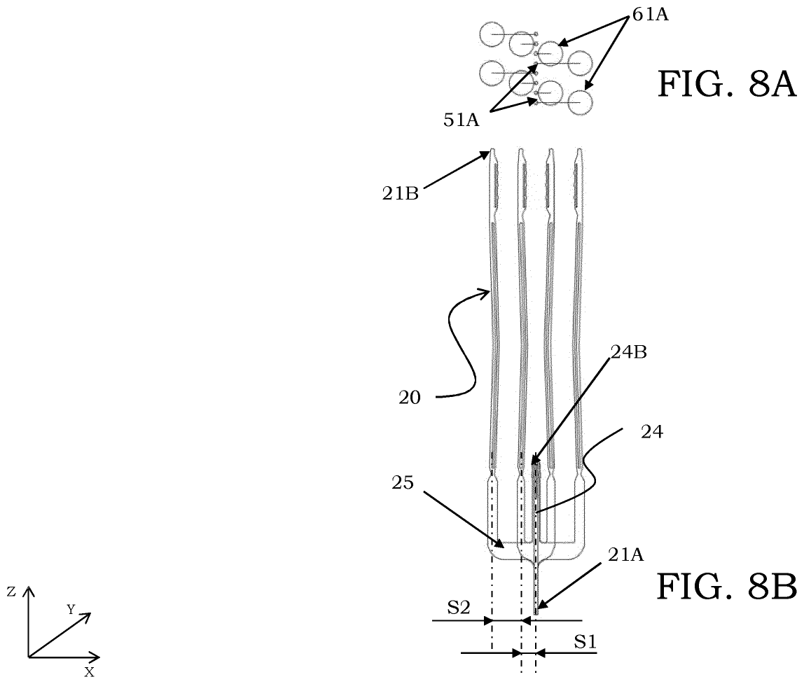

Thanks to the use of the contact pin 24, which is separated by the material bridge 25 with respect to the probe length 23, it is thus possible to redistribute the contact pads 61A of the interface board 60 with the testing apparatus with respect to the contact pads 51A of the device under test 51, as schematically shown in FIGS. 8A and 8B in a top view and a frontal view, respectively. In particular, using contact probes 20 with material bridges 25 of different lengths S1, S2, it is possible to further space the contact pads 61A on the interface board 60, where there are no limits related to the more and more reduced dimensions of the chips and thus of the contact pads 51A of the devices under test 50.

In the example shown in FIGS. 8A and 8B, a linear configuration of the contact pads 51A on the device under test 50 is advantageously transformed, thanks to the use of contact probes 20 provided with contact pins 24, in a matrix configuration with four columns of contact pads 61A on the interface board 60, said contact pads 61A furthermore advantageously having dimensions greater than the contact pads 51A of the device under test 50.

To conclude, the contact probe provided with at least one contact pin can be housed in a probe head with an assembly process from the probe side, wherein the contact probe initially crosses the lower guide in order to reach the upper guide, the presence of the contact pin overcoming the need of post-assembly centring processes.

The presence of the contact pins advantageously allows the contact probes to realise a real spatial transformation at the level of the lower guide, the probes can also be distributed on different levels, thus obtaining a spacing suitable for the direct contact on an interface board towards a testing apparatus to be made by the method known as Direct Attach.

Suitably, the probe head can be made using only two guides, an upper guide and a lower guide, possibly associated with strengthening frames, the contact probes can be pre-deformed and provided with the retaining portion with enlarged diameter in correspondence of the contact pin and the retaining mechanism with corrugated surface in correspondence of the contact head so as to overcome the need for the shifted double guides used in the known solutions, thus guaranteeing a current retaining of the probe inside the corresponding probe head.

The pre-deformation of the contact probes is also able to ease the uniform bending thereof when they are housed in a corresponding probe head, in particular during the pressing contact onto a device under test during the testing operations performed by the probe head, so as to minimize the risk of contact between adjacent probes, also in the absence of a pair of shifted guides as in the known solutions.

The contact probe according to the present invention thereby allows also to overcome the drawbacks of the known solutions comprising double guides for realising an offset of the probes, which, in particular in the presence of a large number of contact probes, can apply a transversal force onto the device under test which is capable of causing undesired displacements.

Furthermore, advantageously according to the present invention, the elasticity of the retaining portion guarantees the passage of the contact pin of the contact probe in a respective guide hole during the assembly operations, as well as the extraction thereof by an operator during possible maintenance operations which for example require the removal and replacement of the probe, still guaranteeing a correct retainment also when the probe head which houses it is not in pressing contact onto a device under test or with a board of a testing apparatus thanks to the contrast made by said retaining portion in correspondence of the contact pin, in association with the possible retaining mechanism in correspondence of the contact head, being capable to hinder the movement of the probe due to gravity when the probe head is separated from the device under test or disassociated from the testing apparatus, as well as in the presence of other transversal forces, such as during cleaning operations normally made by air jets.

Suitably, the retaining portion in correspondence of the contact pin and the retaining mechanism in correspondence of the contact head can be made elastic in a very simple way by an opening adapted to define at least one pair of portions of said elements capable of approaching or moving away one another.

It is furthermore possible to provide the probes with openings made in the probe body thereof in order to form a plurality of longitudinal arms and/or bending necks so as to improve the elasticity of the probes as a whole.

It is thereby possible to make the probes with particularly reduced overall lengths and thus suitable for applications in the most recent technologies, for example for very high frequency applications using only one pair of guides, still guaranteeing the correct retaining of the probes thereinside and without the risk of modifying said probes in a plastic, namely permanent, way.

The contact probes and the corresponding probe head made in this way with limited longitudinal dimensions are also suitable for applications for large devices, such as the most recent 12″ memories, which require the use of a corresponding large-area probe head, which movement is critical and at risk of damage, especially during the certification step. Suitably, the probe head made with contact probes as described above does not need to be subjected to long and delicate operations of assembling and reassembling the mechanics, for example when one or more contact probes should be substituted, accordingly reducing the damage risks thereof.

Obviously, a person skilled in the art, in order to meet contingent and specific needs, may make numerous modifications and variations to the contact probe and probe head described above, all of which fall within the scope of protection of the invention as defined by the following claims.

In particular, it is possible to consider any shape for the openings made in the retaining portion of the contact pin and in the retaining mechanism of the contact head, in addition to the use of possible flexible materials for filling them, as well as any number of longitudinal openings in order to form any number of arms in the probe body.

Finally, it is possible to provide the contact probe of the present invention with further features, such as particular geometrical configurations of the contact tip and head portions, such as for example contact tips with reduced dimensions with respect to the probe body or the presence of coating films.

The invention claimed is:

1. A contact probe having a first end portion which ends with a contact tip configured to abut onto a contact pad of a device under test and a second end portion which ends with a contact head configured to abut onto a contact pad of a board of a testing apparatus, as well as a probe body extended between the first end portion and the second end portion along a longitudinal development axis, the first end portion comprising a first support part, interposed between the probe body and the contact tip, wherein the first support part comprises a contact pin and one probe length which extend parallel to each other along the longitudinal development axis and are separated by an air gap.

2. The contact probe according to claim 1, wherein the first support part further comprises a material bridge configured to connect the contact pin and the probe length along a transversal direction that is orthogonal to the longitudinal development axis, the probe length, the contact pin and the material bridge wholly configuring the first support part as U-shaped.

3. The contact probe according to claim 1, wherein the contact tip is aligned with the contact pin along a further longitudinal axis that is distinct and parallel to the longitudinal development axis of the contact probe.

4. The contact probe according to claim 1, wherein the contact pin comprises a retaining portion in correspondence of a free end thereof, opposite an end that is joined to the material bridge, the retaining portion having a transversal diameter that is greater than a transversal diameter of the contact pin outside the retaining portion, transversal diameter meaning a maximum dimension of a transversal section that is orthogonal with respect to the longitudinal development axis.

5. The contact probe according to claim 4, wherein the retaining portion further comprises a enlarged portion having said transversal diameter greater than the transversal diameter of the contact pin, the enlarged portion being adapted to define an undercut wall of the retaining portion.

6. The contact probe according to claim 4, wherein the retaining portion also comprises a longitudinal opening extending along the further longitudinal axis and is configured to define a pair of portions of the retaining portion capable of approaching and moving away one another if subjected to transversal compressive forces.

7. The contact probe according to claim 1, wherein the second end portion comprises a retaining mechanism configured to generate friction with walls of a guide hole when it houses the second end portion.

8. The contact probe according to claim 1, wherein the second end portion further comprises an opening arranged longitudinally along the longitudinal development axis in a second support part of the second end portion, contiguous to said contact head, the longitudinally arranged opening being configured to define two opposite portions of the second support part capable of approaching and moving away one another if subjected to transversal compressive forces.

9. The contact probe according to claim 1, further comprising a longitudinal slot extending along the probe body and is configured to define therein a pair of arms, parallel to each other and separated by the longitudinal slot.

10. The contact probe according to claim 1, wherein the probe body has a pre-deformed shape with a curvilinear configuration in rest conditions, comprising a bend.

11. The contact probe according to claim 1, further comprising a reduced-section portion which forms a bending neck positioned in the probe body in correspondence of one of the first end portions and second end portion.

12. A probe head for testing the functionality of a device under test comprising:
a plurality of contact probes,
a single upper guide provided with upper guide holes; and
a single lower guide provided with lower guide holes;
the upper guide holes and lower guide holes being adapted to house the plurality of contact probes,
wherein each of the plurality of contact probes has a first end portion which ends with a contact tip configured to abut onto a contact pad of a device under test and a second end portion which ends with a contact head configured to abut onto a contact pad of a board of a testing apparatus, as well as a probe body extended between the first end portion and the second end portion along a longitudinal development axis, the first end portion comprising a first support part, interposed between the probe body and the contact tip,
wherein the first support part comprises a contact pin and one probe length which extend parallel to each other along the longitudinal development axis and are separated by an air gap; and
wherein the lower guide holes comprise first lower guide holes adapted to house the probe lengths of the contact probes and second lower guide holes adapted to house the contact pins of the contact probes.

13. The probe head according to claim 12, wherein the second lower guide holes have a transversal diameter that is equal to or lower than a transversal diameter of a retaining portion of the contact pins.

14. The probe head according to claim 12, further comprising first contact probes and second contact probes having respective contact pins spaced from respective probe lengths by a first distance and by a second distance, respectively, the first distance and second distance being different from each other to spatially redistribute contact pads of an interface board whereonto respective contact heads of the first contact probes and second contact probes abut with respect to contact pads of a device under test whereonto respective contact tips of the first contact probes and second contact probes abut.

15. The probe head according to claim 12, further comprising:
an upper frame, associated with the single upper guide and provided with respective upper openings adapted to house the contact probes; and
a lower frame, associated with the single lower guide and provided with respective lower openings for housing the contact probes.

16. The probe head according to claim 12, wherein the contact probes comprise transversal material bridges adapted to connect the probe lengths and the contact pins positioned in rest conditions at a distance from the lower guide that is greater by a maximum overtravel value of the contact probes, said overtravel being a displacement of the contact tips of the contact probes the longitudinal development axis when in pressing contact onto contact pads of the device under test.

17. The contact probe according to claim 6, wherein the transversal compressive forces are orthogonal to the further longitudinal axis.

18. The contact probe according to claim 7, wherein the retaining mechanism comprises a corrugated surface.

19. The contact probe according to claim 8, wherein the transversal compressive forces are orthogonal to the longitudinal development axis.

20. The contact probe according to claim 10, wherein the probe body has a pre-deformed shape with a curvilinear configuration in rest conditions, comprising two bends.
